(19) United States
(12) Patent Application Publication
(10) Pub. No.: US 2024/0301542 A1
(43) Pub. Date: Sep. 12, 2024

(54) MASK ASSEMBLY AND METHOD FOR MANUFACTURING THE SAME

(71) Applicant: Samsung Display Co., Ltd., Yongin-si (KR)

(72) Inventors: JEONGKUK KIM, Yongin-si (KR); DUCKJUNG LEE, Yongin-si (KR); WONJE CHO, Yongin-si (KR)

(73) Assignee: Samsung Display Co., Ltd., Yongin-si (KR)

(21) Appl. No.: 18/402,248

(22) Filed: Jan. 2, 2024

(30) Foreign Application Priority Data
Mar. 7, 2023 (KR) 10-2023-0030051

(51) Int. Cl. C23C 14/04

(52) U.S. Cl. CPC C23C 14/042

(57) ABSTRACT

A method for manufacturing a mask assembly includes disposing a preliminary mask assembly including a frame having a frame opening and an open sheet having a plurality of first openings and including a first portion and a second portion, welding a preliminary unit mask to the first portion of the open sheet after stretching the preliminary unit mask on the preliminary mask assembly, welding the preliminary unit mask to the second portion of the open sheet, forming a plurality of unit masks by emitting laser onto the preliminary unit mask overlapping the second portion of the open sheet, and forming, in the plurality of unit masks, a plurality of deposition openings overlapping the plurality of first openings by emitting laser. The first portion overlaps the frame, and the second portion extends from the first portion and is disposed between the plurality of first openings.

### CROSS-REFERENCE TO RELATED APPLICATIONS

This application claims priority to and benefits of Korean Patent Application No. 10-2023-0030051 under 35 U.S.C. § 119, filed on Mar. 7, 2023, in the Korean Intellectual Property Office, the entire contents of which are incorporated herein by reference.

### BACKGROUND

### 1. Technical Field

The disclosure herein relates to a mask assembly with which an ultrahigh-resolution display module may be manufactured, and a method for manufacturing the same.

### 2. Description of the Related Art

A display may be manufactured through various processes. For example, a deposition process may be used in a display manufacturing process. In the deposition process for manufacturing a display, a fine metal mask (FMM) adhered to a substrate to deposit an organic material may be used. However, the deposition process is not limited to using the FMM, and a cell unit mask may be used in the deposition process for manufacturing a display.

### SUMMARY

The disclosure provides a mask assembly with which an ultrahigh-resolution display module may be manufactured.

The disclosure also provides a method for manufacturing a mask assembly with which an ultrahigh-resolution display module may be manufactured.

According to an embodiment of the disclosure, a method for manufacturing a mask assembly may include disposing a preliminary mask assembly including a frame having a frame opening and an open sheet having a plurality of first openings and including a first portion and a second portion, welding a preliminary unit mask to the first portion of the open sheet after stretching the preliminary unit mask on the preliminary mask assembly, welding the preliminary unit mask to the second portion of the open sheet, forming a plurality of unit masks by emitting laser onto the preliminary unit mask overlapping the second portion of the open sheet in a plan view, and forming, in the plurality of unit masks, a plurality of deposition openings overlapping the plurality of first openings by emitting laser in a plan view. The first portion may overlap the frame in a plan view, and the second portion may extend from the first portion and may be disposed between the plurality of first openings.

In an embodiment, the welding of the preliminary unit mask to the first portion may include emitting laser on an upper surface of the preliminary unit mask toward a lower surface of the open sheet, and forming, on the upper surface of the preliminary unit mask, a plurality of first welding points overlapping the first portion in a plan view.

In an embodiment, the welding of the preliminary unit mask to the second portion may include emitting laser on an upper surface of the preliminary unit mask toward a lower surface of the open sheet, and forming, on the upper surface of the preliminary unit mask, a plurality of second welding points overlapping the second portion in a plan view.

In an embodiment, the forming of the plurality of unit masks by emitting the laser may include forming a region in which the plurality of unit masks are spaced apart from each other, and the region may be spaced apart from the plurality of second welding points in a plan view.

In an embodiment, the forming of the plurality of deposition openings may include forming the plurality of deposition openings overlapping the plurality of first openings of the open sheet in a plan view.

In an embodiment, the open sheet may have a first thickness and a second thickness less than the first thickness, and the welding of the preliminary unit mask to the second portion may include forming a plurality of second welding points overlapping the open sheet having the first thickness in a plan view.

In an embodiment, the welding of the preliminary unit mask to the second portion may include emitting laser on a lower surface of the open sheet toward an upper surface of the preliminary unit mask, and forming, on the lower surface of the open sheet, a plurality of second welding points overlapping the second portion in a plan view.

In an embodiment, a plurality of first grooves overlapping the second portion of the open sheet in a plan view may be defined in the preliminary unit mask, and the forming of the plurality of unit masks by emitting the laser onto the preliminary unit mask may include forming a first region corresponding to the plurality of first grooves, and forming a second region extending from the first region by emitting laser.

In an embodiment, a plurality of second grooves overlapping the plurality of first openings in a plan view may be defined in the preliminary unit mask, and the forming of the plurality of deposition openings may include forming a third region corresponding the plurality of second grooves, and forming a fourth region extending form the third region by emitting laser.

In an embodiment, the open sheet may be manufactured by a rolling process, and the preliminary unit mask may be manufactured by an electroforming process.

In an embodiment, the preliminary unit mask overlapping the second portion in a plan view may have a thickness in a range of about 10 μm to about 20μ, and the preliminary unit mask overlapping the plurality of first openings in a plan view may have a thickness in a range of about 1 μm to about 10 μm.

In an embodiment of the disclosure, a mask assembly may include a frame including a frame opening, an open sheet covering the frame opening, having a plurality of first opening and including a first portion overlapping the frame in a plan view and a second portion extending from the first portion and disposed between the plurality of first openings, a plurality of unit masks covering the plurality of first openings, each of the plurality of unit masks having a plurality of deposition openings, which overlap the plurality of first openings in a plan view, a plurality of first welding points disposed on an upper surface of a part of the plurality of unit masks, and overlapping the first portion of the open sheet in a plan view, and a plurality of second welding points overlapping the second portion of the open sheet in a plan view. The plurality of unit masks may be spaced apart from each other with a region between the plurality of unit masks, the region may overlap the second portion of the open sheet in a plan view, and the plurality of second welding points may be spaced apart from the region in a plan view.

In an embodiment, the plurality of second welding points may be disposed on upper surfaces of the plurality of unit masks.

In an embodiment, the open sheet may include invar and may be manufactured by a rolling process.

In an embodiment, each of the plurality of unit masks may include invar and may be manufactured by an electroforming process.

In an embodiment, the open sheet may have a thickness in a range of about 20 μm to about 100 μm.

In an embodiment, the open sheet overlapping the plurality of second welding points in a plan view may have a first thickness, the open sheet overlapping the region in a plan view may have a second thickness, and the first thickness may be less than the second thickness.

In an embodiment, the plurality of second welding points may be disposed on a lower surface of the open sheet.

In an embodiment, the region may include a first region formed by an electroforming process and a second region formed by emitting laser, and the first region and the second region may be an integrated opening.

In an embodiment, each of the plurality of deposition openings may include a third region formed by an electroforming process and a fourth region formed by emitting laser, and the third region and the fourth region may be an integrated opening.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view illustrating an electronic device according to an embodiment of the disclosure;

FIG. 1B is an exploded perspective view of an electronic device according to an embodiment of the disclosure;

FIG. 2A is a perspective view of a mask assembly according to an embodiment of the disclosure;

FIG. 2B is an exploded perspective view of a mask assembly according to an embodiment of the disclosure;

FIG. 3 is a schematic cross-sectional view taken along cutting line I-I′ in FIG. 2A;

FIGS. 4A to 4E are schematic cross-sectional views illustrating some operations of a method for manufacturing a mask assembly according to an embodiment of the disclosure;

FIG. 5A is a schematic cross-sectional view illustrating a part of a process for manufacturing a mask assembly according to an embodiment of the disclosure;

FIG. 5B is an enlarged view of region AA′ in FIG. 5A;

FIG. 5C is a schematic cross-sectional view of a mask assembly according to an embodiment of the disclosure;

FIG. 5D is an enlarged view of region AA′ in FIG. 5A;

FIG. 6A is a schematic cross-sectional view illustrating a part of a process for manufacturing a mask assembly according to an embodiment of the disclosure;

FIG. 6B is an enlarged view of region BB′ in FIG. 6A;

FIG. 6C is a schematic cross-sectional view of a mask assembly according to an embodiment of the disclosure;

FIG. 6D is an enlarged view of region CC′ in FIG. 6C;

FIG. 7A is a schematic cross-sectional view illustrating a part of a process for manufacturing a mask assembly according to an embodiment of the disclosure;

FIG. 7B is an enlarged view of region DD′ in FIG. 7A;

FIG. 7C is a schematic cross-sectional view of a mask assembly according to an embodiment of the disclosure; and

FIG. 7D is an enlarged view of region EE′ in FIG. 7C.

### DETAILED DESCRIPTION OF THE EMBODIMENTS

When an element, such as a layer, is referred to as being “on,”“connected to,” or “coupled to” another element or layer, it may be directly on, connected to, or coupled to the other element or layer or intervening elements or layers may be present. When, however, an element or layer is referred to as being “directly on,”“directly connected to,” or “directly coupled to” another element or layer, there are no intervening elements or layers present. To this end, the term “connected” may refer to physical, electrical, and/or fluid connection, with or without intervening elements.

The same reference numerals or symbols refer to the same elements. In addition, in the drawings, thicknesses, ratios, and dimensions of components are exaggerated for effective description of technical content. “And/or” includes all combinations of one or more that the associated elements may define.

Although the terms “first,”“second,” etc. may be used herein to describe various types of elements, these elements should not be limited by these terms. These terms are used to distinguish one element from another element. Thus, a first element discussed below could be termed a second element without departing from the teachings of the disclosure. Singular expressions include plural expressions unless the context clearly indicates otherwise.

Spatially relative terms, such as “beneath,”“below,”“under,”“lower,”“above,”“upper,”“over,”“higher,”“side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,”“an,” and “the” are intended to include the plural forms as well, unless the context clearly indicates otherwise. Moreover, the terms “comprises,”“comprising,”“includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,”“about,” and other similar terms, are used as terms of approximation and not as terms of degree, and, as such, are utilized to account for inherent deviations in measured, calculated, and/or provided values that would be recognized by one of ordinary skill in the art.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Terms “part” or “unit” mean a software component or hardware component that performs a specific function. The hardware component may include, for example, a field-programmable gate array (FPGA) or an application-specific integrated circuit (ASIC). The software component may refer to executable code and/or data used by the executable code in an addressable storage medium. Accordingly, software components may be, for example, object-oriented software components, class components, and task components, and may include processes, functions, properties, procedures, subroutines, program code segments, drivers, firmwares, microcodes, circuits, data, databases, data structures, tables, arrays, or variables.

Unless otherwise defined, all terms (including technical and scientific terms) used in this specification have the same meaning as commonly understood by one of ordinary skill in the art to which the disclosure belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, embodiments of the disclosure will be explained with reference to the drawings.

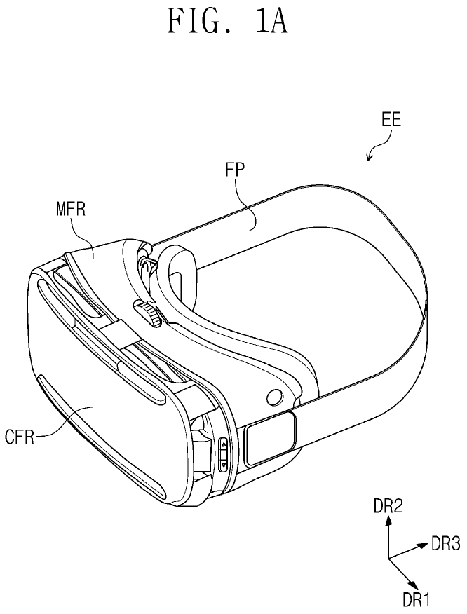

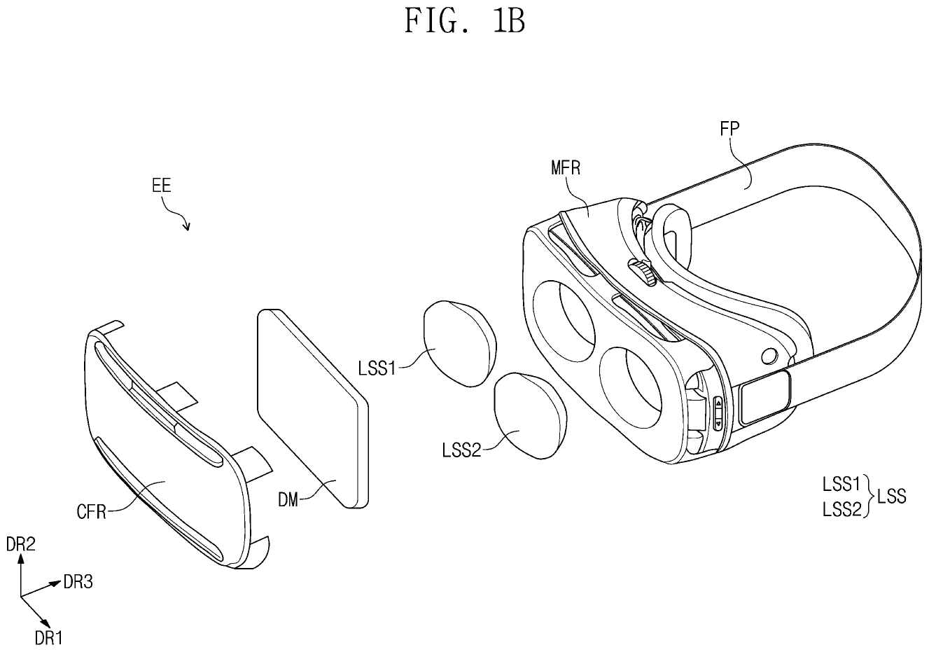

FIG. 1A is a perspective view illustrating an electronic device EE according to an embodiment of the disclosure, and FIG. 1B is an exploded perspective view of the electronic device EE according to an embodiment of the disclosure.

The electronic device EE may be a device activated in response to an electrical signal. For example, the electronic device EE may be a television, a monitor, a billboard, a game console, a personal computer, a notebook computer, a mobile phone, a tablet computer, a navigation system, and a wearable device, but the disclosure is not limited thereto.

As an embodiment of the electronic device EE, a head mounted display (HMD) is illustrated in FIGS. 1A and 1B. The head mounted display may be an electronic device mounted on a user's head to provide a user with a screen on which an image is displayed. The head mounted display may include a see-through type display which provides augmented reality (AR) on the basis of a real external object, and a see-closed type display which provides virtual reality (VR) to the user on a screen independent of the external object.

Referring to FIGS. 1A and 1B, the electronic device EE may include a main frame MFR, a fixing part FP, a lens part LS, a display module DM, and a cover frame CFR.

The main frame MFR may be a part to be worn on a user's face. The main frame MFR may have a shape corresponding to a shape of a user's head (face). The main frame MFR may be coupled to the cover frame CFR to provide an accommodation space in which the lens part LS and the display module DM may be mounted.

The fixing part FP may be a structure for facilitating mounting of the main frame MFR and may include a strap, a band, etc. However, the disclosure is not limited thereto, and the fixing part FP may have various forms such as a helmet or eyeglass temples coupled to the main frame MFR. A length of the fixing part FP may be adjusted according to a user's head circumference.

The lens part LS may be disposed between the display module DM and a user. Light emitted from the display module DM may pass through the lens part LS and be provided to the user. For example, the lens part LS may include at least one of multi-channel lenses, convex lenses, concave lenses, spherical lenses, aspheric lenses, single lenses, composite lenses, standard lenses, narrow-angle lenses, wide-angle lenses, fixed-focal lenses, or varifocal lenses. However, a kind of lenses is not limited thereto.

The lens part LS may include a first lens LSS1 and a second lens LSS2. The first lens LSS1 and the second lens LSS2 may be disposed to respectively correspond to a left eye and a right eye of the user. The first lens LSS1 and the second lens LSS2 may be accommodated inside the main frame MFR.

The display module DM may be provided in a state of being fixed to the main frame MFR, or provided in a state of being attachable thereto or detachable therefrom. The display module DM may provide an image to the user, and the image may include a static image as well as a dynamic image. The electronic device EE may include an ultrahigh-resolution display module DM. An ultrahigh-resolution fine metal mask (FMM) may be used to manufacture the display module DM having an ultrahigh-resolution. The ultrahigh-resolution fine metal mask (FMM) will be described below.

The cover frame CFR may be disposed on a surface of the display module DM to protect the display module DM. The cover frame CFR and the lens part LS may be spaced apart from each other with the display module DM between the cover frame CFR and the lens part LS.

FIGS. 1A and 1B, and the following drawings illustrate a first direction DR1, a second direction DR2, and a third direction DR3, and directions indicated by the first to third directions DR1, DR2, and DR3 described herein are relative concepts, and may be changed into other directions. Direction indicated by the first to third directions DR1, DR2, and DR3 may be respectively described as first to third directions, and thus the same reference numerals or symbols may be used. In the specification, the first direction DR1 and the second direction DR2 may intersect each other, and the third direction DR3 may be a normal direction of a plane defined by the first direction DR1 and the second direction DR2.

A thickness direction of the electronic device EE may be a direction parallel to the third direction DR3, which is a normal direction of a plane defined by the first direction DR1 and the second direction DR2. In the specification, a front surface (or upper surface) and a rear surface (or lower surface) of each member constituting the electronic device EE may be defined with reference to the third direction DR3. In the specification, the wording, “on a plane” means “on a surface” parallel to a plane defined by the first direction DR1 and the second direction DR2, and “on a cross-section” means “on a surface” parallel to the third direction DR3.

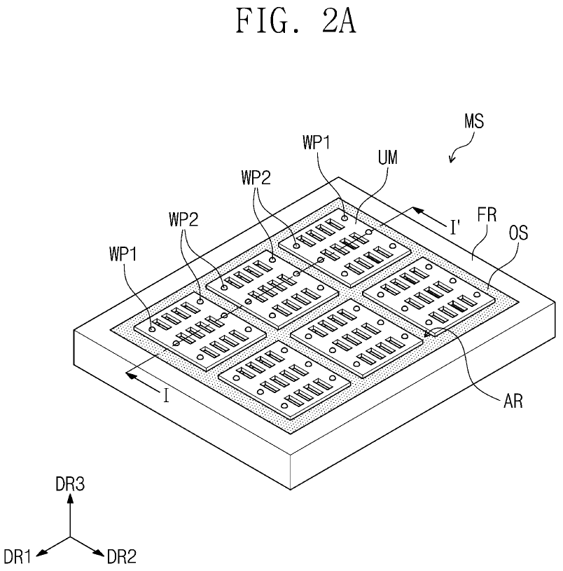

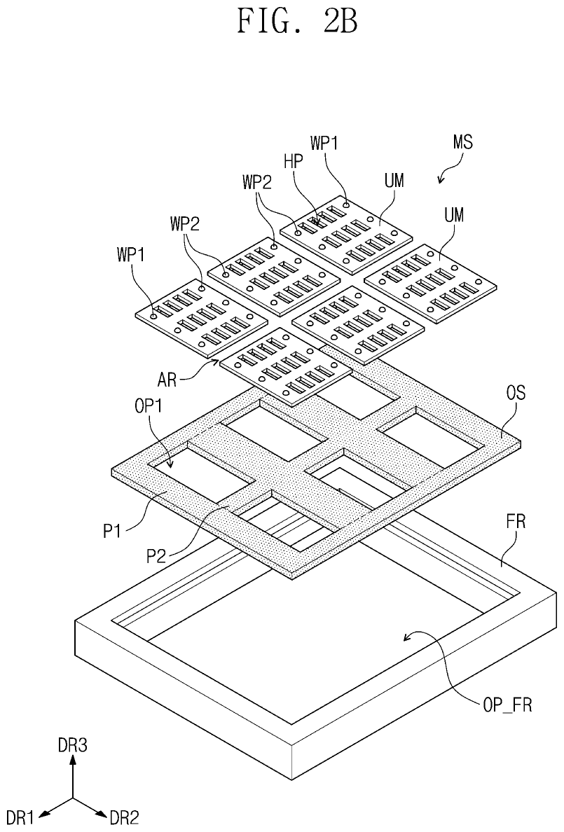

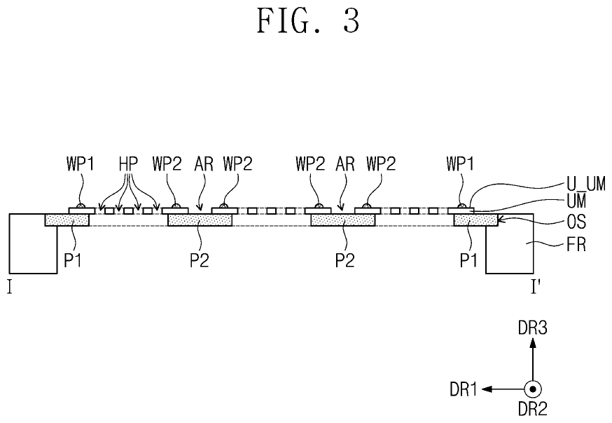

FIG. 2A is a perspective view of a mask assembly MS according to an embodiment of the disclosure, and FIG. 2B is an exploded perspective view of the mask assembly MS according to an embodiment of the disclosure. FIG. 3 is a schematic cross-sectional view taken along cutting line I-I′ in FIG. 2A.

The mask assembly MS may be a display panel process mask MS (hereinafter, a mask assembly) used in a deposition process of a display panel manufacturing process. The mask assembly MS may be adhered to a substrate for the deposition process. The mask assembly MS may include a fine metal mask (FMM) or an open mask OM.

Referring to FIGS. 2A to 3, the mask assembly MS may include a frame FR, an open sheet OS, multiple unit masks UM, multiple first welding points WP1, and multiple second welding points WP2.

A frame opening OP_FR may be defined in the frame FR. The open sheet OS may cover the frame opening OP_FR.

Multiple first openings OP1 may be defined in the open sheet OS. The open sheet OS may include a first portion P1 overlapping the frame FR in a plan view, and a second portion P2 disposed between the first openings OP1. The second portion P2 may extend from the first portion P1. The open sheet OS may include invar produced through a rolling process. Rolled invar may have a low coefficient of thermal expansion (CTE), thereby having a low degree of thermal expansion. The open sheet OS may have a thickness in a range of about 20 μm to about 100 μm.

The unit masks UM may be fine metal masks (FMM). The unit masks UM may cover the first openings OP1. For example, one unit mask UM of the unit masks UM may cover one first opening OP1 of the first openings OP1. Multiple deposition openings HP may be defined in each of the unit masks UM. The deposition openings HP may overlap the first openings OP1 of the open sheet OS in a plan view. For example, the deposition openings HP may overlap one first opening OP1 in a plan view.

FIGS. 2A and 2B schematically illustrate six first openings OP1 and twelve deposition openings HP formed in one unit mask UM, but the disclosure is not limited thereto. For example, numbers of the first openings OP1 and the deposition openings HP may be changed according to a size and resolution of the display panel DP (see FIG. 1B).

The unit masks UM may include invar produced through an electroforming process. Electroformed invar may be produced/processed to have a smaller and more uniform thickness than the rolled invar. For example, the electroformed invar may be produced/processed to have a thickness of less than about 20 μm. The electroformed invar may have a smaller surface roughness than the rolled invar, and may thus be advantageous in forming a hole with a small width. For example, in case that a hole having a size of less than about 5 μm necessary to manufacture an ultrahigh-resolution display module is formed, a display module made of the electroformed invar may have a less defect than a display module made of the rolled invar. The electroformed invar may have a smaller particle size than the rolled invar. Accordingly, the electroformed invar may generate relatively less dust and impurities than the rolled invar in a processing operation, and thus it may be possible to reduce or remove a phenomenon in which the hole is not processed due to the dust and the impurities. For example, the electroformed invar may have more excellent laser processability than the rolled invar.

The unit masks UM may be spaced apart from each other with a region AR between the unit masks UM. For example, the unit masks UM may be spaced apart from each other in the first direction DR1 and the second direction DR2, and the region AR may be defined between the unit masks UM spaced apart from each other. The region AR may be referred to as a space, a spaced region, a spaced space, an in-between space, an in-between region, an intermediate region, or the like. The region AR may overlap the second portion P2 of the open sheet OS in a plan view.

The first welding points WP1 and the second welding points WP2 may be welding traces formed during welding by laser irradiation.

The first welding points WP1 may be disposed on upper surfaces U_UM of some of the unit masks UM. For example, the first welding points WP1 may be disposed on the upper surfaces U_UM of the unit masks UM, adjacent to the frame FR, among the unit masks UM. The first welding points WP1 may overlap the first portion P1 of the open sheet OS in a plan view.

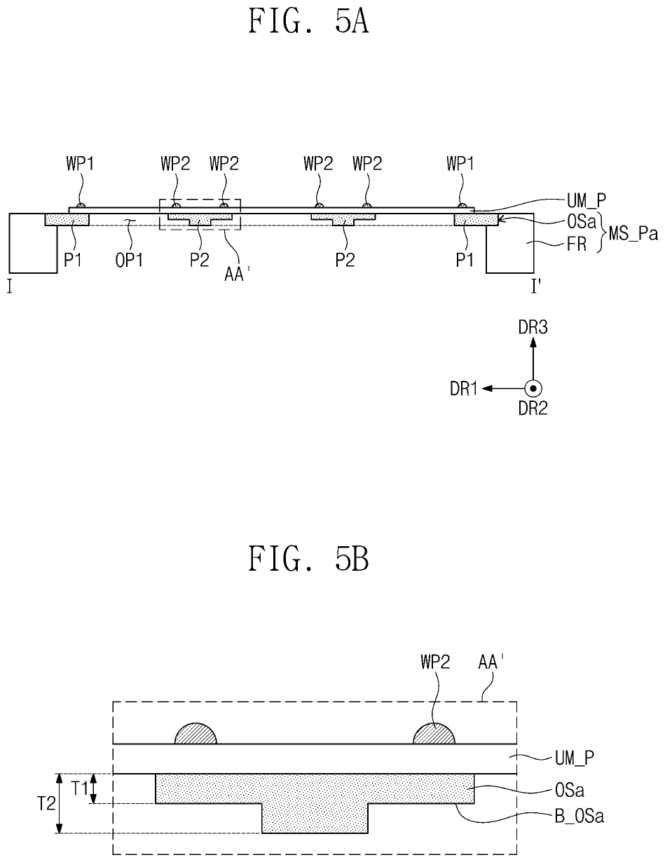

The first welding points WP1 may be disposed on the upper surfaces U_UM of the unit masks UM. For example, the second welding points WP2 may be disposed on the upper surface U_UM of some of the unit masks UM, spaced apart from the frame FR, among the unit masks UM. The second welding points WP2 may overlap the second portion P2 of the open sheet OS in a plan view. The second welding points WP2 may be spaced apart from the region AR on a plane (or in a plan view). However, the disclosure is not limited thereto. For example, the second welding points WP2 may be disposed on a lower surface of the open sheet OS. Detailed description thereof will be made with reference to FIG. 5D.

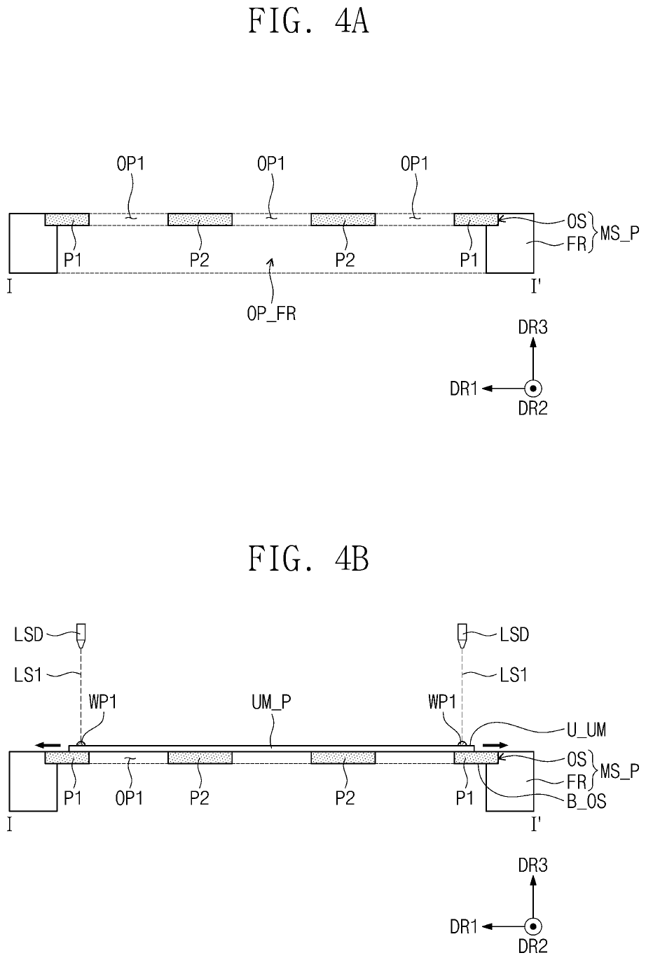

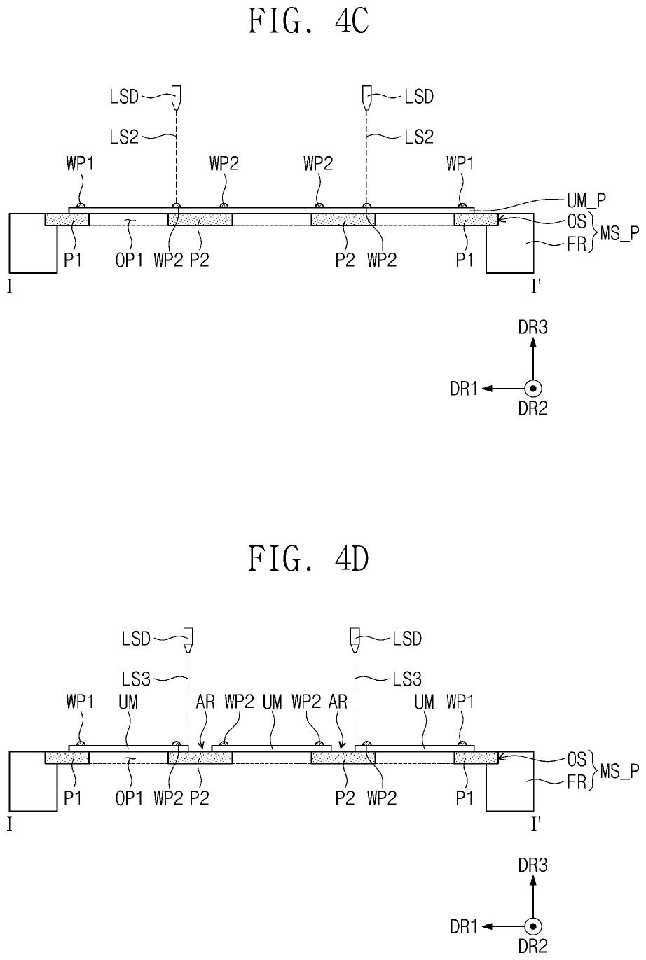

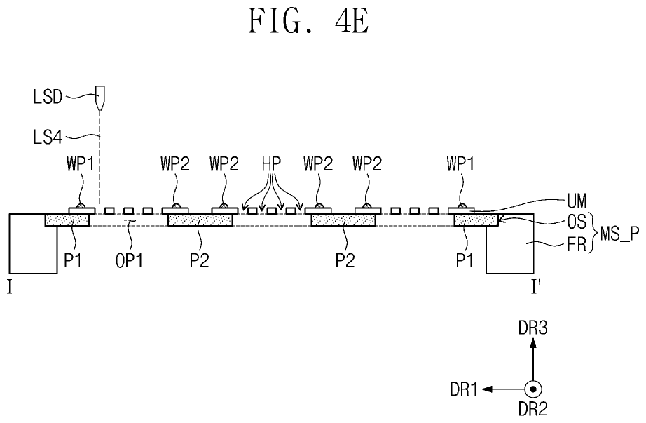

FIGS. 4A to 4E are schematic cross-sectional views illustrating some operations of a method for manufacturing a mask assembly according to an embodiment of the disclosure. Description of FIGS. 4A to 4E will be made with reference to FIGS. 2A to 3, the same/similar reference numerals or symbols are used for components same as/similar to those described with reference to FIGS. 2A to 3, and duplicate descriptions therefor will be omitted.

The method for manufacturing a mask assembly according to an embodiment may include an operation of disposing a preliminary mask assembly including a frame having a frame opening defined therein, and an open sheet having multiple first openings defined therein and including a first portion and a second portion, an operation of welding a preliminary unit mask to the first portion of the open sheet by (or after) stretching the preliminary unit mask on the preliminary mask assembly, an operation of welding the preliminary unit mask to the second portion of the open sheet, an operation of forming multiple unit masks by emitting laser onto the preliminary unit mask overlapping the second portion of the open sheet, and an operation of forming, in the unit masks, multiple deposition openings overlapping the first openings by emitting laser. The first portion may overlap the frame in a plan view, and the second portion may extend from the first portion and may be disposed between the first openings.

Referring to FIG. 4A, the method for manufacturing a mask assembly may include an operation of disposing a preliminary mask assembly MS_P including a frame FR and an open sheet OS. A frame opening OP_FR may be defined in the frame FR, and multiple first openings OP1 may be defined in the open sheet OS.

The open sheet OS may include a first portion P1 overlapping the frame FR and a second portion P2 disposed between the first openings OP1. The second portion P2 may extend from the first portion P1. The open sheet OS may be manufactured by a rolling process. The open sheet OS may include invar produced through a rolling process. A rolled invar may have a low coefficient of thermal expansion (CTE), thereby having a low degree of thermal expansion.

Referring to FIG. 4B, the method for manufacturing a mask assembly may include an operation of welding the preliminary unit mask UM_P to the first portion P1 of the open sheet OS by (or after) stretching the preliminary unit mask UM_P on the preliminary mask assembly MS_P.

The operation of welding the preliminary unit mask UM_P to the first portion P1 may include an operation of emitting laser LS1 on an upper surface U_UM of the preliminary unit mask UM_P toward a lower surface B_OS of the open sheet OS, and an operation of forming, on the upper surface U_UM of the preliminary unit mask UM_P, multiple first welding points WP1 overlapping the first portion P1 in a plan view. The operation of welding the preliminary unit mask UM_P to the first portion P1 may be a process of fixing the preliminary unit mask UM_P to the open sheet OS.

The preliminary unit mask UM_P may be manufactured by an electroforming process. The preliminary unit mask UM_P may include invar produced through an electroforming process. Electroformed invar may be produced/processed to have a small and uniform thickness, and has characteristics of a lower surface roughness and smaller particle size.

The open sheet OS may have a greater thickness than a thickness of the preliminary unit mask UM_P. The preliminary unit mask UM_P overlapping the second portion P2 of the open sheet OS may have a greater thickness than a thickness of the preliminary unit mask UM_P overlapping the first openings OP1 of the open sheet OS in a plan view. For example, the open sheet OS may have a thickness in a range of about 20 μm to about 100 μm, the preliminary unit mask UM_P overlapping the second portion P2 of the open sheet OS may have a thickness in a range of about 10 μm to about 20 μm, and the preliminary unit mask UM_P overlapping the first openings OP1 of the open sheet OS may have a thickness in a range of about 1 μm to about 10 μm. According to an embodiment, the preliminary unit mask UM_P may include the electroformed invar, and thus be manufactured/processed to have a thickness in a range of about 1 μm to about 20 μm.

The preliminary unit mask UM_P may be stretched and disposed on an upper surface of the open sheet OS. Thereafter, a laser device LSD may emit first laser LS1 on the upper surface U_UM of the preliminary unit mask UM_P toward the lower surface B_OS of the open sheet OS. A part of the preliminary unit mask UM_P may be melted, and the first welding points WP 1 may be formed on the upper surface U_UM of the preliminary unit mask UM_P irradiated with the first laser LS1. The first welding points WP1 may be welding traces formed during welding by emitting the first laser LS1. The first welding points WP1 may overlap the first portions P1 in a plan view.

According to an embodiment, multiple deposition openings HP (see FIG. 4E) may be first formed in the unit masks UM (see FIG. 4E), and the unit masks UM may be stretched and welded to the open sheet OS. However, according to another embodiment, the deposition openings HP may be formed after stretching and welding the preliminary unit mask UM_P in a sheet state to the open sheet OS, and therefore the pixel position accuracy (PPA) may be improved.

Referring to FIG. 4C, the method for manufacturing a mask assembly may include an operation of welding the preliminary unit mask UM_P to the second portion P2 of the open sheet OS.

The operation of welding the preliminary unit mask UM_P to the second portion P2 may include an operation of emitting laser LS2 on the upper surface U_UM (see FIG. 4B) of the preliminary unit mask UM_P toward the lower surface B_OS (see FIG. 4B) of the open sheet OS, and an operation of forming, on the upper surface U_UM of the preliminary unit mask UM_P, the second welding points WP2 overlapping the second portion P2 in a plan view. The operation of welding the preliminary unit mask UM_P to the second portion P2 may be a process of welding (or fixing) the preliminary unit mask UM_P by each cell unit before cutting the preliminary unit mask UM_P by each cell unit.

The laser device LSD may emit the second laser LS2 on the upper surface U_UM of the preliminary unit mask UM_P toward the lower surface B_OS of the open sheet OS. The second laser LS2 and the first laser LS1 may be the same or different from each other. A part of the preliminary unit mask UM_P may be melted and the second welding points WP2 may be formed on the upper surface U_UM of the preliminary unit mask UM_P irradiated with the second laser LS2. The second welding points WP2 may be welding traces formed during welding by emitting the second laser LS2. The second welding points WP2 may overlap the second portion P2 in a plan view.

Referring to FIG. 4D, the method for manufacturing a mask assembly may include an operation of forming the unit masks UM by emitting laser onto the preliminary unit mask UM_P (see FIG. 4C) overlapping the second portion P2 of the open sheet OS in a plan view.

The operation of forming the unit masks UM by emitting laser LS3 onto the preliminary unit mask UM_P may include an operation of forming a region AR in which the unit masks UM are spaced apart from each other. The operation of forming the unit masks UM by emitting the laser LS3 onto the preliminary unit mask UM_P may be a process of cutting the preliminary unit mask UM_P into each cell unit.

The laser device LSD may emit the third laser LS3 toward the preliminary unit mask UM_P overlapping the second portion P2 in a plan view. The third laser LS3 and the first and second lasers LS1 and LS2 (see FIGS. 4B and 4C) may be the same or different from each other. A region irradiated with the third laser LS3 may be spaced from the second welding points WP2 on a plane (or in a plan view). The third laser LS3 may be emitted on a region between two second welding points WP2 to remove a part of the preliminary unit mask UM_P. As a result, the preliminary unit mask UM_P may be separated into the unit masks UM, and the unit masks UM may be spaced apart from each other. The region AR may be formed between the unit masks UM spaced apart from each other by removing a part of the preliminary unit mask UM_P.

FIGS. 4B to 4D each schematically illustrate two laser devices LSD respectively emitting first to third lasers LS1, LS2, and LS3, but the disclosure is not limited thereto. For example, one laser device may emit laser while moving, or a large-area laser device may simultaneously emit multiple laser beams in a static state.

Referring to FIG. 4E, the method for manufacturing a mask assembly may include an operation of forming the deposition openings HP overlapping the first openings OP1 in the unit masks UM in a plan view by emitting laser LS4.

The operation of forming the deposition openings HP in each of the unit masks UM may include an operation of forming the deposition openings HP overlapping the first openings OP1 of the open sheet OS in a plan view. The operation of forming the deposition openings HP in each of the unit masks UM may be a process of forming a hole through which a deposition material is provided. For example, the deposition material sprayed from a deposition source in a deposition process may pass through the deposition openings HP, and the deposition material may be deposited on a work substrate to form deposition patterns corresponding to the deposition openings HP.

The laser device LSD may emit a fourth laser LS4 toward upper surfaces of the unit masks UM. For example, the laser device LSD may emit the fourth laser LS4 while moving in a direction parallel to the first direction DR1 and the second direction DR2. The fourth laser LS4 and the first to third lasers LS1, LS2, and LS3 (see FIGS. 4B to 4D) may be the same or different from each other. The fourth laser LS4 may remove some of the unit masks UM. The deposition openings HP may be formed from the removed some of the unit masks UM. The deposition openings HP may overlap the first openings OP1 of the open sheet OS in a plan view. For example, the deposition openings HP may overlap one first openings OP1 of the first openings OP1.

FIG. 4E schematically illustrates one laser device LSD emitting the fourth laser LS4, but the disclosure is not limited thereto. For example, multiple laser devices may emit laser in a fixed position, or a large-area laser device may simultaneously emit multiple laser beams in a static state.

Referring to FIGS. 4C to 4E, the open sheet OS may include invar produced through a rolling process. A rolled invar may have a lower coefficient of thermal expansion (CTE) than an electroformed invar, thereby having a low degree of thermal expansion. The unit masks UM may include invar produced through an electroforming process. The electroformed invar may have excellent laser processability than the rolled invar.

According to an embodiment, since the preliminary unit mask UM_P is welded to the open sheet OS by each cell unit and is cut into each cell unit, the unit masks UM may be fixed to the open sheet OS including the rolled invar having a low coefficient of thermal expansion (CTE). Accordingly, in case that the deposition openings HP are formed by emitting laser onto the unit masks UM, a degree of expansion of the unit masks UM due to heat may become smaller than a typical process of laser cutting the entire surface with laser instead of cutting by each cell unit. Since the unit masks UM in which the deposition openings HP are formed may include the electroformed invar having excellent laser processability, defects in an ultrahigh-resolution display module manufactured by using the unit masks UM may be reduced.

FIG. 5A is a schematic cross-sectional view illustrating a part of a process for manufacturing a mask assembly according to an embodiment of the disclosure. FIG. 5B is an enlarged view of region AA′ in FIG. 5A. FIG. 5A may illustrate a process corresponding to FIG. 4C. Description of FIGS. 5A and 5B will be made with reference to FIGS. 2A to 3, and 4C, the same/similar reference numerals or symbols are used for components same as/similar to those described with reference to FIGS. 2A to 3, and 4C, and duplicate descriptions therefor will be omitted.

Referring to FIGS. 5A and 5B, a preliminary mask assembly MS_Pa may include a frame FR and an open sheet OSa. The open sheet OSa may include a first thickness T1 and a second thickness T2 greater than the first thickness T1.

A method for manufacturing a mask assembly may include an operation of welding a preliminary unit mask UM_P to a second portion P2 of the open sheet OSa. The operation of welding the preliminary unit mask UM_P to the second portion P2 may form multiple second welding points WP2 overlapping the open sheet OSa having the first thickness T1.

A laser device may emit a second laser LS2 (see FIG. 4C) onto an upper surface U_UM (see FIG. 5C) of the preliminary unit mask UM_P toward a lower surface B_OSa of the open sheet OS. The open sheet OSa irradiated with laser may have the first thickness T1, and the open sheet OSa not irradiated with laser may have the second thickness T2. The second welding points WP2 may be formed on the upper surface U_UM of the preliminary unit mask UM_P, while overlapping the open sheet OSa having the first thickness T1.

In case that the open sheet OSa has a thickness greater than or equal to about 100 μm, energy for welding, formed by laser irradiation, may not be sufficiently transferred to the open sheet OSa. According to an embodiment, since the second welding points WP2 are formed overlapping the open sheet OSa having the first thickness T1, the energy for welding may be sufficiently transferred to the open sheet OSa to facilitate welding.

FIG. 5C is a schematic cross-sectional view of a mask assembly MSa according to an embodiment of the disclosure. The mask assembly MSa in FIG. 5C may be manufactured from the preliminary mask assembly MS_Pa including the open sheet OSa. FIG. 5C is a schematic cross-sectional view corresponding to the mask assembly in FIG. 3.

Referring to FIG. 5C, the open sheet OSa overlapping the second welding points WP2 may have the first thickness T1, and the open sheet OSa overlapping a region AR may have the second thickness T2. The first thickness T1 may be smaller than the second thickness T2.

FIG. 5D is an enlarged view of region AA′ in FIG. 5A. Description for FIG. 5D will be made with reference to FIGS. 4C and 5A, and description for the same reference numerals or symbols will be omitted.

Referring to FIG. 5D, the method for manufacturing a mask assembly may include an operation of welding the preliminary unit mask UM_P to the second portion P2 of the open sheet OSa. The operation of welding the preliminary unit mask UM_P to the second portion P2 may include an operation of emitting laser onto the lower surface B_OSa of the open sheet OSa toward the upper surface U_UM of the preliminary unit mask UM_P, and an operation of forming, on the lower surface B_OSa of the open sheet OSa, multiple second welding points WP2a overlapping the second portion P2 in a plan view.

A laser device may emit laser onto the lower surface B_OSa of the open sheet OSa toward the upper surface U_UM of the preliminary unit mask UM_P. A part of the open sheet OSa irradiated with laser may be melted to form the second welding points WP2a. The second welding points WP2a may overlap the second portion P2 in a plan view. The open sheet OSa irradiated with laser may have the first thickness T1, and the open sheet OSa not irradiated with laser may have the second thickness T2. The second welding points WP2a may be disposed on the lower surface B_OSa of the open sheet OSa having the first thickness T1.

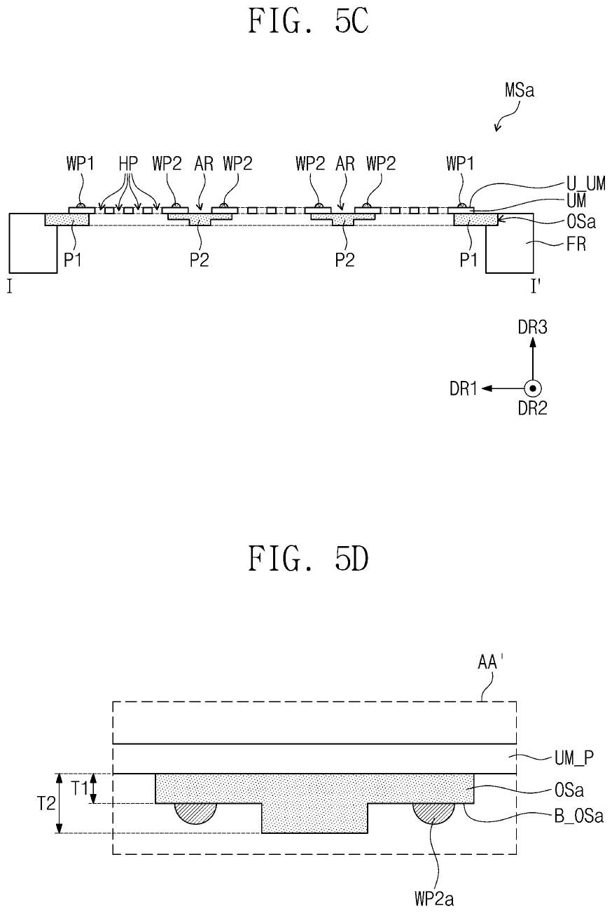

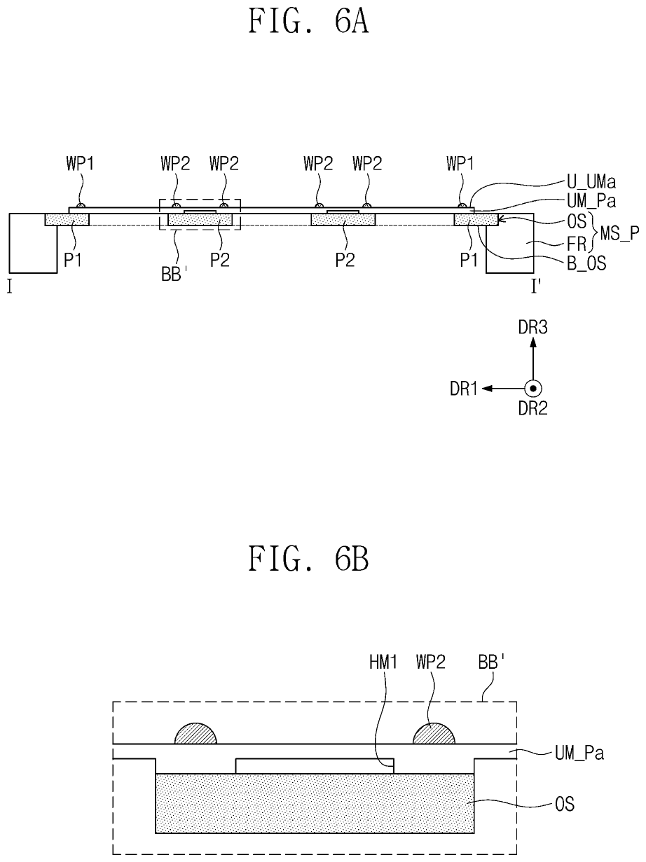

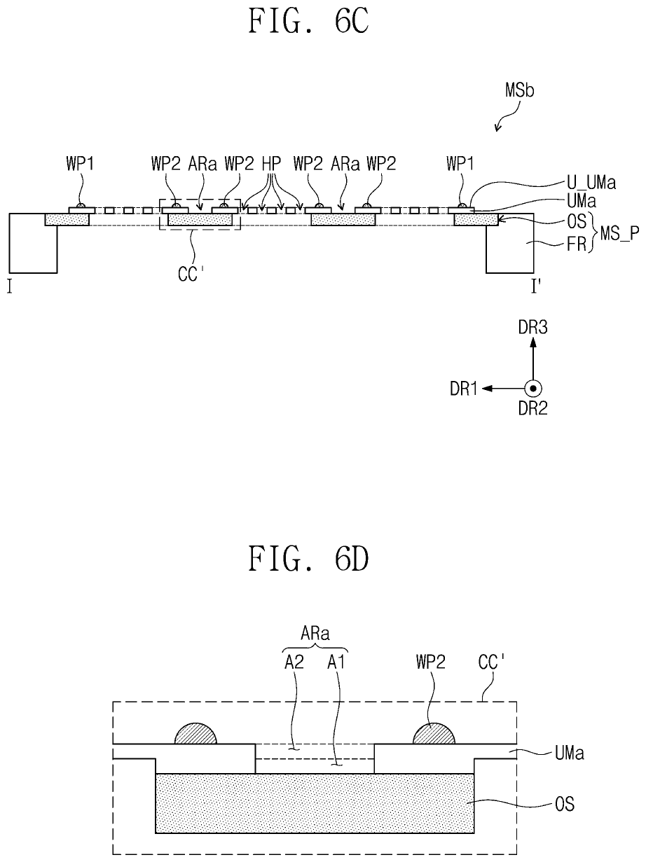

FIG. 6A is a schematic cross-sectional view illustrating a part of a process for manufacturing a mask assembly according to an embodiment of the disclosure. FIG. 6B is an enlarged view of region BB′ in FIG. 6A. FIG. 6A may illustrate a process corresponding to FIG. 4C. Description for FIGS. 6A and 6B will be made with reference to FIGS. 2A to 3, and 4C, the same/similar reference numerals or symbols are used for components same/similar to those described in FIGS. 2A to 3, and 4C, and duplicate description therefor will be omitted.

Referring to FIGS. 6A and 6B, a preliminary unit mask UM_Pa may be welded to a second portion P2 of an open sheet OS. Multiple first grooves HM1 overlapping the second portion P2 of the open sheet OS in a plan view may be defined in the preliminary unit mask UM_Pa.

An operation of welding the preliminary unit mask UM_Pa to the second portion P2 may include an operation of emitting laser onto an upper surface U_UMa of the preliminary unit mask UM_Pa toward a lower surface B_OS of the open sheet OS, and an operation of forming, on the upper surface U_UMa of the preliminary unit mask UM_Pa, multiple second welding points WP2 overlapping the second portion P2 in a plan view.

A laser device may emit laser onto a region which is spaced apart from the first grooves HM1 of the preliminary unit mask UM_Pa on a plane (or in a plan view). A part of the preliminary unit mask UM_Pa irradiated with laser may be melted to form the second welding points WP2. The second welding points WP2 may overlap the second portion P2 of the open sheet OS in a plan view, and may not overlap the first grooves HM1 of the preliminary unit mask UM_Pa in a plan view.

In case that the preliminary unit mask UM_Pa has a thickness of less than about 10 μm, the preliminary unit mask UM_Pa may not be readily welded. According to an embodiment, a part of the preliminary unit mask UM_Pa in which the first grooves HM1 are not defined may have a greater thickness than a thickness of a part of the preliminary unit mask UM_Pa in which the first grooves HM1 are defined. Since the second welding points WP2 are formed in the part of the preliminary unit mask UM_Pa in which the first grooves HM1 are not defined, the preliminary unit mask UM_Pa may be readily welded.

FIG. 6C is a schematic cross-sectional view of a mask assembly MSb according to an embodiment of the disclosure. FIG. 6D is an enlarged view of region CC′ in FIG. 6C. The mask assembly MSb in FIG. 6C may be manufactured from the preliminary unit mask UM_Pa in FIG. 6A. Description for FIG. 6C will be made with reference to FIGS. 3, 6A and 6B, the same/similar reference numerals or symbols are used for components same/similar to those described in FIG. 3, and duplicate description therefor will be omitted.

Referring to FIGS. 6C and 6D, a method for manufacturing a mask assembly may include an operation of forming multiple unit masks UMa by emitting laser onto the preliminary unit mask UM_Pa (see FIG. 6A). The operation of forming the unit masks UMa by emitting laser onto the preliminary unit mask UM_Pa may include an operation of forming a first region A1 corresponding to the first grooves HM1 (see FIG. 6B), and an operation of forming a second region A2 extending from the first region A1 by emitting laser.

A laser device may emit laser onto the upper surface U_UMa of the preliminary unit mask UM_Pa (see FIG. 6A). The laser may be emitted onto a region overlapping the first grooves HM1 in a plan view. For example, the laser may be emitted on a region between two second welding points WP2 to partially remove the preliminary unit mask UM_Pa. As a result, the preliminary unit mask UM_Pa may be separated into the unit masks UMa, and the unit masks UMa may be spaced apart from each other.

The preliminary unit mask UM_Pa may be partially removed to form a region ARa between the unit masks UMa spaced apart from each other. The region ARa may include a first region A1 and a second region A2. The first region A1 may be a region corresponding to the first grooves HM1 concavely formed in the preliminary unit mask UM_Pa. For example, the first region A1 may be a region formed by an electroforming process. The second region A2 may be a region in which the preliminary unit mask UM_Pa is partially removed by emitted laser. The second region A2 may extend from the first region A1, and the first region A1 and the second region A2 may be formed as an integrated opening.

As the preliminary unit mask UM_Pa has a smaller thickness, the preliminary unit mask UM_Pa may be readily cut by emitting laser. According to an embodiment, a part of the preliminary unit mask UM_Pa in which the first grooves HM1 are defined may have a smaller thickness than a thickness of a part of the preliminary unit mask UM_Pa in which the first grooves HM1 are not defined. Since the preliminary unit mask UM_Pa is cut by emitting laser onto the part of the preliminary unit mask UM_Pa in which the first grooves HM1 are defined, cutting may be readily performed.

The operation of forming the unit masks UMa by emitting laser onto the preliminary unit mask UM_Pa may include an operation of forming multiple deposition openings HP. Thereafter, the operation of forming the deposition openings HP may be substantially the same as the process described in FIG. 4E.

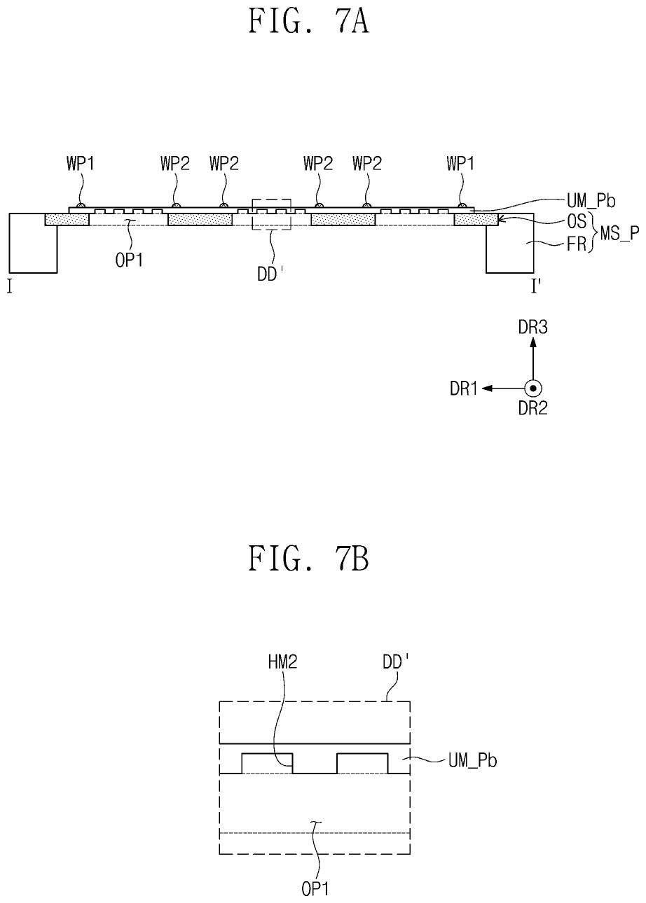

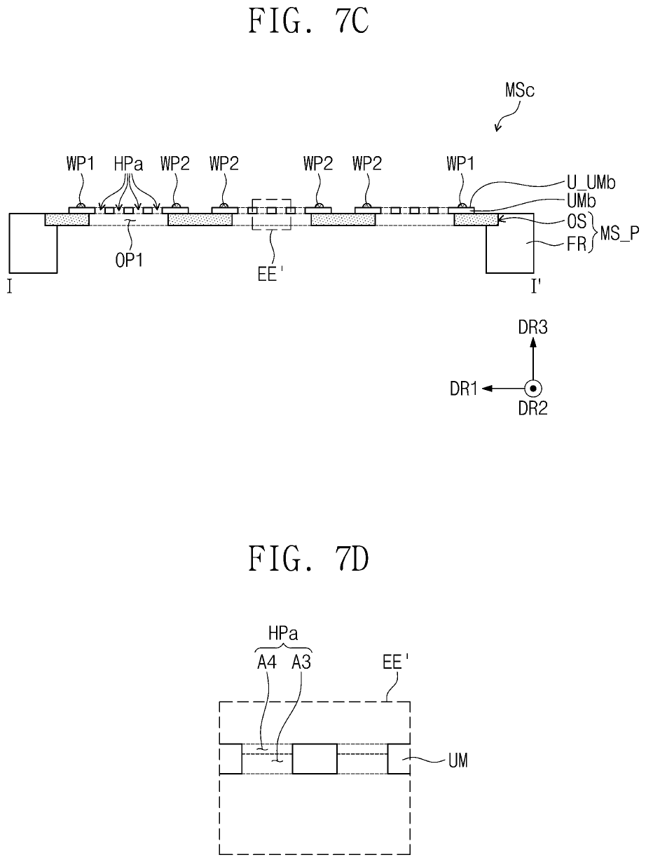

FIG. 7A is a schematic cross-sectional view illustrating a part of a process for manufacturing a mask assembly according to an embodiment of the disclosure. FIG. 7B is an enlarged view of region DD′ in FIG. 7A. FIG. 7A may illustrate a process corresponding to FIG. 4C. Description for FIGS. 7A and 7B will be made with reference to FIGS. 2A to 3, and 4C, the same/similar reference numerals or symbols are used for components same/similar to those described in FIGS. 2A to 3, and 4C, and duplicate description therefor will be omitted.

Referring to FIGS. 7A and 7C, a preliminary unit mask UM_Pb may be welded to a second portion P2 (see FIG. 4C) of an open sheet OS. Multiple second grooves HM2 respectively overlapping multiple first openings OP1 in a plan view may be defined in the preliminary unit mask UM_Pb. For example, one first opening OP1 of the first openings OP1 may overlap the second grooves HM2 in a plan view.

FIG. 7C is a schematic cross-sectional view of a mask assembly MSc according to an embodiment of the disclosure. FIG. 7D is an enlarged view of region EE′ in FIG. 7C. The mask assembly MSc in FIG. 7C may be manufactured from the preliminary unit mask UM_Pb. FIG. 7C is a schematic cross-sectional view corresponding to the mask assembly in FIG. 3C. Description for FIG. 7C will be made with reference to FIGS. 3, 7A and 7B, the same/similar reference numerals or symbols are used for components same/similar to those described in FIG. 3, and duplicate description therefor will be omitted.

Referring to FIGS. 7C and 7D, a method for manufacturing a mask assembly may include an operation of forming multiple deposition openings HPa in multiple unit masks UMb. The operation of forming the deposition openings HPa in the unit masks UMb may include an operation of forming a third region A3 corresponding to the second grooves HM2 (see FIG. 7B), and an operation of forming a fourth region A4 extending from the third region A3 by emitting laser.

A laser device may emit laser onto upper surfaces U_UMb of the unit masks UMb. The laser may be emitted onto a region overlapping the second grooves HM2 in a plan view. For example, the laser may be emitted onto the region, of the first openings OP1 of the open sheet OS, overlapping the second grooves HM2 to partially remove the unit masks UMb. As a result, multiple deposition openings HPa may be formed from the removed part of the unit masks UMb. The deposition openings HPa may respectively overlap the first openings OP1 of the open sheet OS in a plan view.

The deposition openings HPa may include the third region A3 and the fourth region A4. The third region A3 may be a region corresponding to the second grooves HM2 (see FIG. 7B) concavely formed in the preliminary unit mask UM_Pb (see FIG. 7A). For example, the third region A3 may be a region formed by an electroforming process. The fourth region A4 may be a region in which the unit masks UMb are partially removed by emitted laser. The fourth region A4 may extend from the third region A3, and the third region A3 and the fourth region A4 may be formed as an integrated opening.

As the deposition openings HPa have a smaller thickness, the deposition openings HPa may be readily formed by emitting laser. According to an embodiment, the second grooves HM2 may be defined in the preliminary unit mask UM_Pb, and a part of the preliminary unit mask UM_Pb in which the second grooves HM2 are defined may have a smaller thickness than a thickness of a part of the preliminary unit mask UM_Pb in which the second grooves HM2 are not defined. Since the deposition openings HPa are formed by emitting laser onto the part of the preliminary unit mask UM_Pb in which the second grooves HM2 are defined, the deposition openings HPa may be readily formed.

According to what is described above, since multiple deposition openings are formed after stretching and welding a preliminary unit mask in a sheet state to an open sheet, pixel position accuracy (PPA) may be improved.

Since the preliminary unit mask is welded to the open sheet by each cell unit, and is cut into each cell unit, multiple unit masks may be fixed to the open sheet having a low coefficient of thermal expansion. Accordingly, in case that the deposition openings are formed by emitting laser onto the unit masks, the unit masks may have a low degree of thermal expansion. Since the unit masks in which the deposition openings are formed include electroformed invar having excellent laser processability, defects in an ultrahigh-resolution display module manufactured by using the unit masks may be reduced.

A first thickness may be smaller than a second thickness. Since multiple second welding points are formed overlapping the open sheet having the first thickness, energy for welding may be sufficiently transferred to the open sheet to facilitate welding.

Since the second welding points are formed in a part of the preliminary unit mask in which multiple first grooves are not defined, the preliminary unit mask may be readily welded. Since the preliminary unit mask is cut by emitting laser onto a part of the preliminary unit mask in which the first grooves are defined, cutting may be readily performed.

Since the deposition openings are formed by emitting laser onto a part of the preliminary unit mask in which the second grooves are defined, the deposition openings may be readily formed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method for manufacturing a mask assembly, the method comprising:
disposing a preliminary mask assembly including a frame having a frame opening and an open sheet having a plurality of first openings and including a first portion and a second portion;
welding a preliminary unit mask to the first portion of the open sheet after stretching the preliminary unit mask on the preliminary mask assembly;
welding the preliminary unit mask to the second portion of the open sheet;
forming a plurality of unit masks by emitting laser onto the preliminary unit mask overlapping the second portion of the open sheet in a plan view; and
forming, in the plurality of unit masks, a plurality of deposition openings overlapping the plurality of first openings in a plan view by emitting laser, wherein
the first portion overlaps the frame in a plan view, and
the second portion extends from the first portion and is disposed between the plurality of first openings.

2. The method of claim 1, wherein the welding of the preliminary unit mask to the first portion comprises:
emitting laser on an upper surface of the preliminary unit mask toward a lower surface of the open sheet; and
forming, on the upper surface of the preliminary unit mask, a plurality of first welding points overlapping the first portion in a plan view.

3. The method of claim 1, wherein the welding of the preliminary unit mask to the second portion comprises:
emitting laser on an upper surface of the preliminary unit mask toward a lower surface of the open sheet; and
forming, on the upper surface of the preliminary unit mask, a plurality of second welding points overlapping the second portion in a plan view.

4. The method of claim 3, wherein
the forming of the plurality of unit masks by emitting the laser comprises forming a region in which the plurality of unit masks are spaced apart from each other, and
the region is spaced apart from the plurality of second welding points in a plan view.

5. The method of claim 1, wherein the forming of the plurality of deposition openings comprises forming the plurality of deposition openings overlapping the plurality of first openings of the open sheet in a plan view.

6. The method of claim 1, wherein
the open sheet has a first thickness and a second thickness less than the first thickness, and
the welding of the preliminary unit mask to the second portion comprises forming a plurality of second welding points overlapping the open sheet having the first thickness in a plan view.

7. The method of claim 6, wherein the welding of the preliminary unit mask to the second portion comprises:
emitting laser on a lower surface of the open sheet toward an upper surface of the preliminary unit mask; and
forming, on the lower surface of the open sheet, a plurality of second welding points overlapping the second portion in a plan view.

8. The method of claim 1, wherein
a plurality of first grooves overlapping the second portion of the open sheet in a plan view are defined in the preliminary unit mask, and
the forming of the plurality of unit masks by emitting the laser onto the preliminary unit mask comprises:
forming a first region corresponding to the plurality of first grooves; and
forming a second region extending from the first region by emitting laser.

9. The method of claim 1, wherein
a plurality of second grooves overlapping the plurality of first openings in a plan view are defined in the preliminary unit mask, and
the forming of the plurality of deposition openings comprises:
forming a third region corresponding the plurality of second grooves; and
forming a fourth region extending form the third region by emitting laser.

10. The method of claim 1, wherein
the open sheet is manufactured by a rolling process, and
the preliminary unit mask is manufactured by an electroforming process.

11. The method of claim 1, wherein
the preliminary unit mask overlapping the second portion in a plan view has a thickness in a range of about 10 μm to about 20 μ, and
the preliminary unit mask overlapping the plurality of first openings in a plan view has a thickness in a range of about 1 μm to about 10 μm.

12. A mask assembly comprising:
a frame including a frame opening;
an open sheet covering the frame opening, having a plurality of first opening and including a first portion overlapping the frame in a plan view and a second portion extending from the first portion and disposed between the plurality of first openings;
a plurality of unit masks covering the plurality of first openings, each of the plurality of unit masks having a plurality of deposition openings, which overlap the plurality of first openings in a plan view;
a plurality of first welding points disposed on an upper surface of a part of the plurality of unit masks, and overlapping the first portion of the open sheet in a plan view; and
a plurality of second welding points overlapping the second portion of the open sheet in a plan view, wherein
the plurality of unit masks are spaced apart from each other with a region between the plurality of unit masks,
the region overlaps the second portion of the open sheet in a plan view, and
the plurality of second welding points are spaced apart from the region in a plan view.

13. The mask assembly of claim 12, wherein the plurality of second welding points are disposed on upper surfaces of the plurality of unit masks.

14. The mask assembly of claim 12, wherein the open sheet comprises invar and is manufactured by a rolling process.

15. The mask assembly of claim 12, wherein each of the plurality of unit masks comprises invar and is manufactured by an electroforming process.

16. The mask assembly of claim 12, wherein the open sheet has a thickness in a range of about 20 μm to about 100 μm.

17. The mask assembly of claim 12, wherein
the open sheet overlapping the plurality of second welding points in a plan view has a first thickness,
the open sheet overlapping the region in a plan view has a second thickness, and
the first thickness is less than the second thickness.

18. The mask assembly of claim 17, wherein the plurality of second welding points are disposed on a lower surface of the open sheet.

19. The mask assembly of claim 12, wherein
the region comprises a first region formed by an electroforming process and a second region formed by emitting laser, and the first region and the second region are an integrated opening.

20. The mask assembly of claim 12, wherein
each of the plurality of deposition openings comprises a third region formed by an electroforming process and a fourth region formed by emitting laser, and
the third region and the fourth region are an integrated opening.
